(19) United States
(12) Patent Application Publication
(10) Pub. No.: US 2025/0174921 A1
(43) Pub. Date: May 29, 2025

(54) PANEL AND MANUFACTURING METHOD

(71) Applicant: ALPS ALPINE CO., LTD., Tokyo (JP)

(72) Inventors: Kenichi NISHIMURO, Fukushima (JP); Takahito MAFUNE, Fukushima (JP)

(21) Appl. No.: 19/040,186

(22) Filed: Jan. 29, 2025

Related U.S. Application Data
(63) Continuation of application No. PCT/JP2023/008368, filed on Mar. 6, 2023.

(30) Foreign Application Priority Data
Aug. 22, 2022 (JP) 2022-131653

(51) Int. Cl. H01R 12/59; H01R 13/405; H05K 1/18

(52) U.S. Cl. CPC H01R 12/59; H01R 13/405; H05K 1/181; H05K 2201/10151

(57) ABSTRACT

A panel includes: an insulating film; a molding resin integrally formed with the insulating film by injection molding; an electric circuit provided on a back surface of the insulating film; and a flexible wiring board that includes a connecting part connected to a connection terminal of the electric circuit at one end of the connecting part and that extends from a rear surface of the molding resin through the molding resin. Both surfaces of the flexible wiring board are coated with an adhesive resin.

### CROSS-REFERENCE TO RELATED APPLICATIONS

The present application is a continuation application of International Application No. PCT/JP2023/008368, filed on Mar. 6, 2023, and designating the U.S., which is based upon and claims priority to Japanese Patent Application No. 2022-131653, filed on Aug. 22, 2022. The contents of these applications are incorporated herein by reference in their entirety.

### BACKGROUND

### Technical Field

The present disclosure relates to a panel and a manufacturing method.

### Background Art

For example, Japanese Laid-Open Patent Publication No. 2021-068755 discloses a technology for integrally molding a circuit film on one principal surface of a molded body by molding the molded body by injection molding.

### SUMMARY

However, in the technology disclosed in Patent Document 1, because wiring is arranged between the molded body and the circuit film, there is a possibility that a gap is formed between the molded body and the circuit film, and water enters into the gap, the gap appears as a shade of color on the exterior, and the quality may deteriorate.

In addition, in the technology disclosed in Patent Document 1, it is necessary to inject the molten resin into the mold twice for filling a first area of the mold with the molten resin and filling a second area of the mold with the molten resin. Therefore, the apparatus configuration and manufacturing process may be complicated, and there may be an unfilled part of the molten resin, and manufacturing time and cost may be increased.

According to one embodiment, a panel includes: an insulating film; a molding resin integrally formed with the insulating film by injection molding; an electric circuit provided on a back surface of the insulating film; and a flexible wiring board that includes a connecting part connected to a connection terminal of the electric circuit at one end of the connecting part and that extends from a rear surface of the molding resin through the molding resin, wherein both surfaces of the flexible wiring board are coated with an adhesive resin.

According to one embodiment, a high-quality panel can be manufactured at a low cost in a short time.

### BRIEF DESCRIPTION OF THE DRAWINGS

FIG. 1 is a diagram schematically illustrating a laminated structure of a panel according to one embodiment;

FIG. 2 is a diagram schematically illustrating a manufacturing method of a panel according to one embodiment;

FIG. 3 is a diagram schematically illustrating a manufacturing method of a panel according to one embodiment;

FIG. 4 is a diagram schematically illustrating a manufacturing method of a panel according to one embodiment;

FIG. 5 is a diagram schematically illustrating a manufacturing method of a panel according to one embodiment;

FIG. 6 is a diagram schematically illustrating a manufacturing method of a panel according to one embodiment;

FIG. 7 is a diagram schematically illustrating a manufacturing method of a panel according to one embodiment; and

FIG. 8 is a diagram schematically illustrating a manufacturing method of a panel according to one embodiment.

### DETAILED DESCRIPTION OF THE INVENTION

One embodiment will be described below with reference to the drawings.

### Configuration of Panel 100

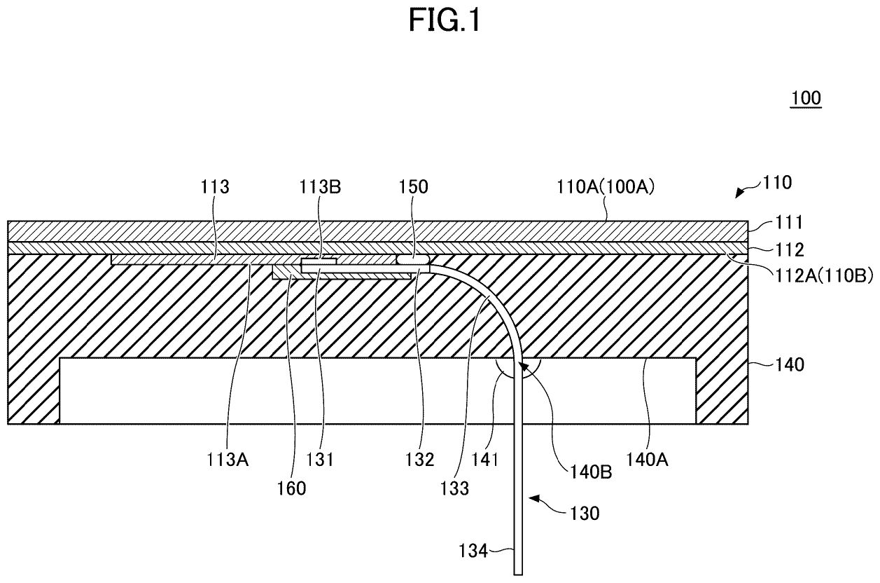

FIG. 1 schematically illustrates a laminated structure of a panel 100 according to one embodiment. As illustrated in FIG. 1, the panel 100 includes a decorative film 110, an FPC 130, a molding resin 140, an adhesive member 150, and a protective member 160.

The decorative film 110 decorates the surface of the panel 100 by being provided on the surface of the panel 100 such that the entire surface of the panel 100 is covered. A front surface 110A of the decorative film 110 serves as an operation surface 100A on which a proximity operation by an operator is performed. The decorative film 110 includes a base film 111, a decorative layer 112, and an electrostatic sensor 113.

The base film 111 is a transparent film-shaped member. The base film 111 is an example of an “insulating film”. For example, the base film 111 is formed by using a transparent film-shaped member (for example, poly methyl methacrylate (PMMA), polycarbonate (PC), urethane, ABS, and the like) having flexibility and insulating properties.

The decorative layer 112 represents a decorative pattern (for example, grain pattern, metal pattern, and the like) presented on the front surface (that is, the operation surface 100A) of the panel 100. The decorative layer 112 is provided over the entire back surface of the base film 111. For example, the decorative layer 112 is formed by printing color inks (for example, CMYK) of a plurality of colors on the back surface of the base film 111 in pixel units, according to the pattern presented on the front surface of the panel 100.

The electrostatic sensor 113 is provided on a back surface 112A (the surface on the molding resin 140 side) of the decorative layer 112. The electrostatic sensor 113 is an example of an “electric circuit”. The electrostatic sensor 113 has a thin film shape. The electrostatic sensor 113 can detect the proximity operation by the operator by changing the electrostatic capacity according to the proximity distance of the operator to the operation surface 100A. The electrostatic sensor 113 has a connection terminal 113B on a principal surface 113A facing the molding resin 140. For example, the electrostatic sensor 113 is formed by screen printing on the back surface 112A of the decorative layer 112. Because the electrostatic sensor 113 is provided integrally with the decorative film 110, alignment and the like at the time of injection molding are not required.

The FPC 130 is an example of a “flexible wiring board” and is a flexible sheet-shaped and band-shaped wiring board. The FPC 130 has a connecting part 131 at one end. The FPC 130 is physically and electrically connected to the connection terminal 113B of the electrostatic sensor 113 by a conductive adhesive at the connecting part 131. A part of one end of the FPC 130 is buried in the molding resin 140 by injection molding the molding resin 140. In addition, a part of the other end of the FPC 130 extends to the outside of the molding resin 140 from an opening 140B provided on a rear surface 140A (the surface opposite to the surface facing the decorative film 110) of the molding resin 140 by injection molding the molding resin 140.

The FPC 130 includes a first extending part 132 and a second extending part 133. The first extending part 132 extends from the connecting part 131 in the direction along the decorative film 110. The second extending part 133 extends in the direction away from the decorative film 110, following the first extending part 132.

Both sides of the FPC 130 are coated with an adhesive resin, so that adhesive resin layers 134 are formed on the both sides. Accordingly, in the panel 100 according to one embodiment, it is possible to enhance the adhesion between the FPC 130 (the part buried in the molding resin 140) and the molding resin 140, and it is possible to reduce the formation of the gap between the FPC 130 (the part buried in the molding resin 140) and the molding resin 140.

The molding resin 140 is a resin member integrally formed with a back surface 110B of the decorative film 110 by injection molding. The molding resin 140 is a member serving as the base of the panel 100, and is formed into a predetermined shape according to the application by injection molding. The rear surface 140A (the surface opposite to the surface facing the decorative film 110) of the molding resin 140 is provided with the opening 140B through which the FPC 130 extends from the molding resin 140. The opening 140B is sealed by applying a sealant 141 from the outside. In the panel 100 according to one embodiment, by providing the sealant 141, it is possible to reduce the intrusion of water or the like into the inside of the molding resin 140 from the opening 140B.

The adhesive member 150 is provided between the first extending part 132 of the FPC 130 and the back surface 110B of the decorative film 110. The adhesive member 150 adheres the first extending part 132 of the FPC 130 to the back surface 110B of the decorative film 110. That is, the adhesive member 150 serves to fill the gap between the first extending part 132 of the FPC 130 and the back surface 110B of the decorative film 110. In the panel 100 according to one embodiment, by providing the adhesive member 150, it is possible to reduce the formation of the gap between the back surface 110B of the decorative film 110 and the molding resin 140.

The protective member 160 is a sheet-shaped member that covers the connecting part 131 of the FPC 130 in a state of being connected to the connection terminal 113B of the electrostatic sensor 113. For example, a heat-resistant tape is used as the protective member 160. In the panel 100 according to one embodiment, by providing the protective member 160, it is possible to protect the connecting part 131 of the FPC 130 from the molten resin during injection molding, and it is possible to reduce the influence (softening, and the like) of heat and pressure on the conductive adhesive that bonds the connecting part 131 of the FPC 130 and the connection terminal 113B of the electrostatic sensor 113.

### Manufacturing Method of Panel 100

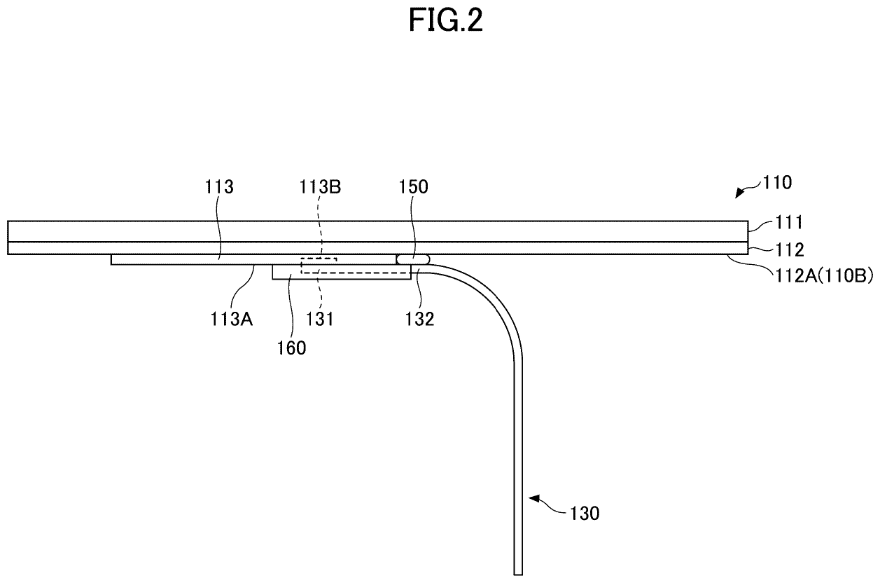

A manufacturing method of the panel 100 according to one embodiment will be described below with reference to FIGS. 2 to 8. FIGS. 2 to 8 schematically illustrate the method of manufacturing the panel 100 according to one embodiment.

### FPC Connecting Step

First, as illustrated in FIG. 2, the FPC 130 is connected to the decorative film 110 (provided with the decorative layer 112 and the electrostatic sensor 113). Specifically, the connecting part 131 provided at one end of the FPC 130 is bonded to the connection terminal 113B provided at the principal surface 113A of the electrostatic sensor 113 using the conductive adhesive. The first extending part 132 of the FPC 130 is bonded to the back surface 110B of the decorative film 110 by the adhesive member 150. The protective member 160 is attached to the connecting part 131 of the FPC 130 so as to cover the connecting part 131 of the FPC 130.

### Decorative Film Installation Step

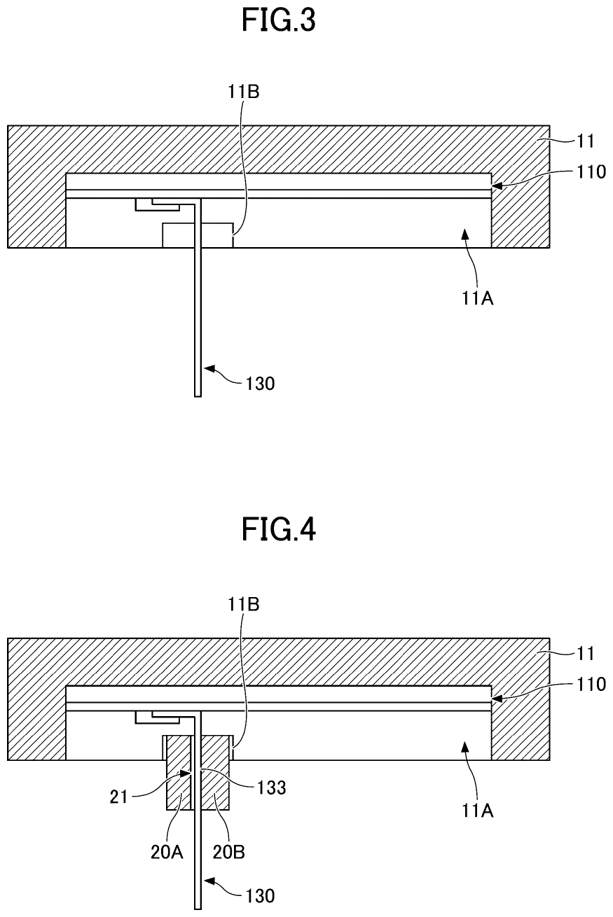

Next, as illustrated in FIG. 3, the decorative film 110 with the FPC 130 connected thereto is installed on the inner wall surface (inner bottom surface) facing a space 11A of a first mold 11.

### Protection Block Installation Step

Next, as illustrated in FIG. 4, a columnar protection block 20 is installed in the first mold 11, and the second extending part 133 of the FPC 130 is protected by the protection block 20. At this time, the protection block 20 can be divided into a first protection block 20A and a second protection block 20B. By coupling the second protection block 20B to the first protection block 20A such that a groove 21 formed in the first protection block 20A is closed while the second extending part 133 of the FPC 130 is arranged in the groove 21, the second extending part 133 of the FPC 130 can be protected. The protection block 20 is fitted into a recess 11B of the first mold 11 to be arranged and fixed in a predetermined position. In the protection block installation step, because the second extending part 133 of the FPC 130 can be arranged in the protection block 20 in a state where a second mold 12 is not fastened to the first mold 11, the second extending part 133 of the FPC 130 can be readily protected.

### Fastening Step

Next, as illustrated in FIG. 5, the second mold 12 is fastened to the first mold 11. As a result, a cavity 10 closed by the first mold 11 and the second mold 12 is formed. Because a through hole 12A is formed in the second mold 12, the protection block 20 can be fitted in the through hole 12A.

### Injection Step

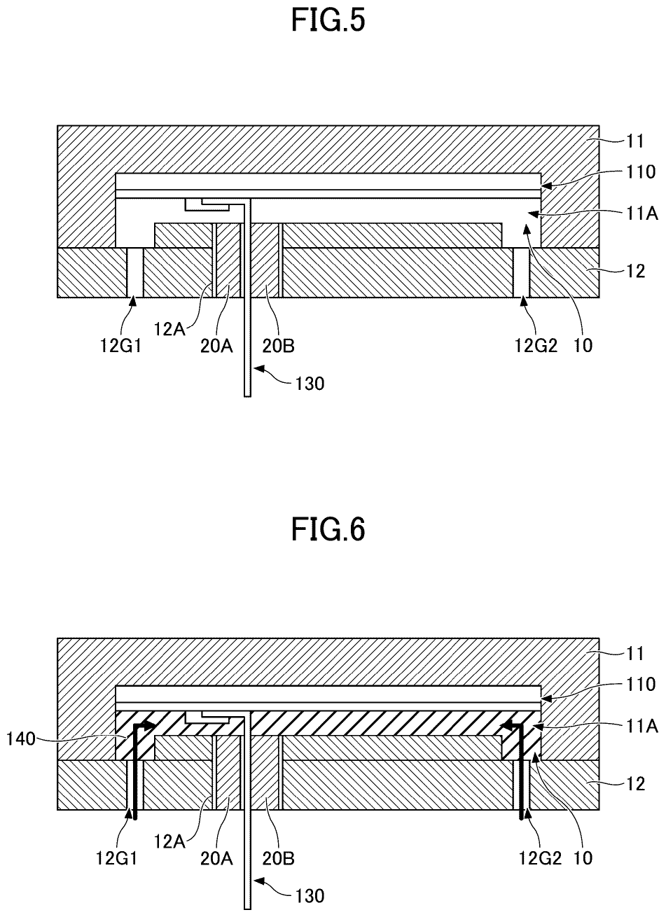

Next, as illustrated in FIG. 6, a molten resin is simultaneously injected from two gates 12G1 and 12G2 provided in the second mold 12, into the cavity 10 closed by the first mold 11 and the second mold 12, thereby injection molding the molding resin 140.

Here, in the injection step, suitable injection conditions (gate location, gate opening number, gate opening diameter, injection pressure, and the like) determined in advance by simulation are used. Thus, in the injection step, the molten resin injected from the gate 12G1 (first surface side of the second extending part 133 of the FPC 130) and the molten resin injected from the gate 12G2 (second surface side of the second extending part 133 of the FPC 130) can cross at the position of the second extending part 133 of the FPC 130 (that is, the molten resins can arrive at the second extending part 133 of the FPC 130 approximately simultaneously).

Therefore, in the injection step, pressure can be applied equally to the first surface and the second surface of the second extending part 133 of the FPC 130 at the same timing. Accordingly, it is possible to minimize the application of a pressing force from the molten resin in a biased direction to the second extending part 133 of the FPC 130, thereby reducing the occurrence of defects such as breakage and disconnection of the FPC 130.

Further, in the injection step, because the molding resin 140 can be formed by one injection, the apparatus configuration and manufacturing process can be simplified, thereby reducing the increase in time and cost for manufacturing the panel 100.

Further, in the injection step, because the first extending part 132 of the FPC 130 is bonded to the back surface 110B of the decorative film 110, it is possible to reduce the formation of the gap between the back surface 110B of the decorative film 110 and the molding resin 140, and it is possible to reduce the intrusion of water into the gap and the appearance of the gap as a shade of color on the exterior.

Further, in the injection step, because the second extending part 133 of the FPC 130 is protected by the protection block 20 in the through hole 12A of the second mold 12, it is possible to prevent the second extending part 133 of the FPC 130 from interfering with the second mold 12.

Further, in the injection step, because the connecting part 131 of the FPC 130 is protected by the protective member 160, it is possible to reduce the influence of heat and pressure applied from the molten resin on the conductive adhesive that bonds the connecting part 131 of the FPC 130 and the connection terminal 113B of the electrostatic sensor 113.

Further, in the injection step, because the adhesive resin layers 134 are formed on both sides of the FPC 130, it is possible to enhance the adhesion between the second extending part 133 of the FPC 130 (the part buried in the molding resin 140) and the molding resin 140 by the adhesive resin layers 134. Therefore, in the injection step, it is possible to reduce the formation of the gap between the second extending part 133 of the FPC 130 (the part buried in the molding resin 140) and the molding resin 140, and it is possible to reduce the intrusion of water into the gap.

### Panel Taking Out Step

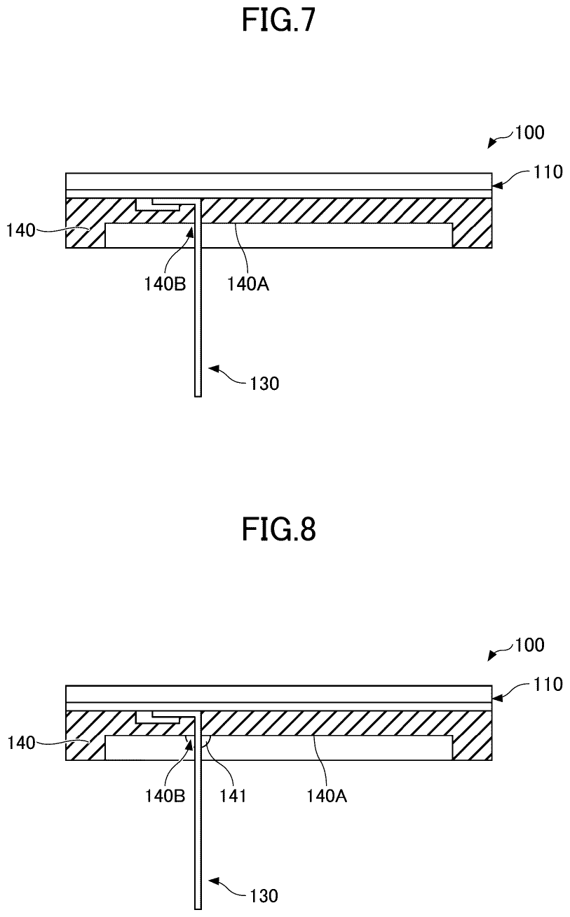

Next, as illustrated in FIG. 7, after the second mold 12 and the protection block 20 are removed, the panel 100 is taken out from the first mold 11. In the panel 100 that has been taken out, the decorative film 110 is integrally provided on the front face of the molding resin 140 having a predetermined outer shape (the same shape as the cavity 10 closed by the first mold 11 and the second mold 12), and the FPC 130 extends from the opening 140B of the rear surface 140A of the molding resin 140.

### Sealant Application Step

Next, as illustrated in FIG. 8, the opening 140B of the molding resin 140 is sealed by applying the sealant 141 to the opening 140B of the molding resin 140 in the panel 100 from the outside. Thus, it is possible to reduce the intrusion of water into the molding resin 140 through the opening 140B.

Although one embodiment of the present invention has been described in detail above, the present invention is not limited to this embodiment, and various changes or modifications are possible within the scope of the present invention as described in the claims.

What is claimed is:

1. A panel comprising:
an insulating film;
a molding resin integrally formed with the insulating film by injection molding;
an electric circuit provided on a back surface of the insulating film; and
a flexible wiring board that includes a connecting part connected to a connection terminal of the electric circuit at one end of the connecting part and that extends from a rear surface of the molding resin through the molding resin, wherein
adhesive resin layers are formed on both surfaces of the flexible wiring board.

2. The panel according to claim 1, further comprising:
a protective member that covers the connecting part of the flexible wiring board.

3. The panel according to claim 1, wherein the flexible wiring board includes:
a first extending part that extends from the connecting part in a direction along the insulating film; and
a second extending part that extends in a direction away from the insulating film following the first extending part, and
the panel further comprises an adhesive member that adheres the first extending part of the flexible wiring board to the insulating film.

4. The panel according to claim 1, wherein
the molding resin includes, on the rear surface, an opening through which the flexible wiring board extends, and
the opening is sealed with a sealant from outside.

5. A manufacturing method of a panel, the manufacturing method comprising:
installing an insulating film, with a flexible wiring board connected to the insulating film, in a space of a first mold;
installing a protection block for protecting the flexible wiring board;
fastening a second mold to the first mold; and
injection molding a molding resin by injecting a molten resin into the space of the first mold, thereby forming a panel in the first mold, wherein
in the injection molding, an injection condition is used in which a molten resin injected from a first surface side of the flexible wiring board and a molten resin injected from a second surface side of the flexible wiring board arrive at the flexible wiring board approximately simultaneously.

6. The manufacturing method according to claim 5, wherein adhesive resin layers are formed on both surfaces of the flexible wiring board.

7. The manufacturing method according to claim 5, wherein the panel includes a protective member that covers a connecting part that is connected to a connection terminal of an electric circuit in the flexible wiring board.

8. The manufacturing method according to claim 5, wherein
the flexible wiring board includes:
a first extending part that extends from a connecting part that is connected to a connection terminal of an electric circuit, in a direction along the insulating film; and
a second extending part that extends in a direction away from the insulating film following the first extending part, and
the panel further includes an adhesive member that adheres the first extending part of the flexible wiring board to the insulating film.

9. The manufacturing method according to claim 5, wherein
the molding resin includes, on a rear surface, an opening through which the flexible wiring board extends, and
the opening is sealed with a sealant from outside.
